(19) United States
(12) Patent Application Publication
(10) Pub. No.: US 2025/0033339 A1
(43) Pub. Date: Jan. 30, 2025

(54) PROCESS AND DEVICE FOR ASSEMBLY OF VAN DER WAALS HETEROSTRUCTURES

(71) Applicant: The University of Manchester, Manchester (GB)

(72) Inventors: Roman Gorbachev, Manchester (GB); Alex Summerfield, Macclesfield (GB); Nicholas Clark, Manchester (GB); Wendong Wang, Manchester (GB); Matthew Hamer, Sherbrooke (CA)

(21) Appl. No.: 18/856,983

(22) PCT Filed: Apr. 24, 2023
(86) PCT No.: PCT/GB2023/051075

§ 371 Date: Oct. 15, 2024

(30) Foreign Application Priority Data
Apr. 25, 2022 (GB) 2205998.4

(51) Int. Cl. B32B 37/00; H01L 21/683

(52) U.S. Cl. CPC B32B 37/025; H01L 21/6835; B32B 2457/00; H01L 2221/68368

(57) ABSTRACT

Provided herein is a method for transferring a material from a first substrate to a second substrate via a flexible intermediate substrate comprising a support layer and a metallic adhesion layer. The method comprises lifting the material from the first substrate with the intermediate substrate, the lifting comprising adhering the material to the metallic adhesion layer by Van der Waals adhesion between the material and the metallic adhesion layer. The method comprises depositing the material from the intermediate substrate on to the second substrate, the depositing comprising adhering the material to the second substrate by Van der Waals adhesion between the material and the second substrate. Also provided herein is a method of forming a heterostructure by removing material from one or more substrates via a flexible intermediate substrate comprising a support layer and metallic adhesion layer. A flexible substrate for performing the same is also provided.

### FIELD

This relates to methods of transferring materials for forming, or assembling, Van der Waals heterostructures, and to a device for use in the forming of such heterostructures.

### BACKGROUND

Layer-by-layer assembly of two dimensional (2D) materials into Van der Waals (VdW) heterostructures (structures assembled and held together by Van der Waals adhesion between the layers, rather than by chemical bonding) has become a large, and rapidly developing, field. For example, artificially assembled VdW heterostructures can form unique quantum and optoelectronic metamaterials with atomically sharp and clean interfaces.

One of the key challenges in assembling VdW heterostructures is the mechanical transfer of two-dimensional materials (or 2DMs) onto other layers/target substrates. Some 2D material transfer techniques rely on the use of polymer membranes, which are used to manipulate the 2DMs and/or the VdW heterostructures, and eventually deposit them onto a target substrate for the fabrication of transistors and optoelectronic (and other) devices. While the use of polymer membranes offers certain advantages (namely their mechanical properties and high adhesion to 2DMs), there are also downsides: the use of polymer membranes can lead to contamination of the resulting devices, with polymer residue remaining inside or on the surface of the completed heterostructures, as well as limiting the operational conditions (such as temperature and chemical environment) over which the assembly of VdW heterostructures can be performed.

It is therefore desirable to provide means for alternative assembly of VdW heterostructures.

### SUMMARY

Described herein is a method for transferring a material from a flexible intermediate substrate to a second substrate, the flexible intermediate substrate comprising a support layer and a metallic adhesion layer. The method comprises depositing the material from the intermediate substrate on to the second substrate, the depositing comprising adhering the material to the second substrate by Van der Waals adhesion between the material and the second substrate and delaminating the material from the metallic adhesion layer of the intermediate substrate.

A flexible substrate for depositing material onto a bulk substrate is also described, the flexible intermediate substrate comprising: a support layer, wherein the support layer is formed of an inorganic material; and a metallic adhesion layer.

Described herein is also a method for transferring a material from a first substrate to a second substrate, the transferring being via a flexible intermediate substrate comprising a support layer and a metallic adhesion layer. The method comprises lifting the material from the first substrate with the intermediate substrate, the lifting comprising adhering the material to the metallic adhesion layer by Van der Waals adhesion between the material and the metallic adhesion layer. The method comprises depositing the material from the intermediate substrate on to the second substrate, the depositing comprising adhering the material to the second substrate by Van der Waals adhesion between the material and the second substrate. This method facilitates the simple and quick assembly of 2D heterostructures by Van der Waal adhesion, reducing the cost and assembly time required in the manufacture of devices involving the same.

The transfer technique and corresponding device described herein opens a pathway for improved industrial scale fabrication of various VdW heterostructures for both commercial and experimental purposes.

Optionally, the Van der Waals adhesion between the material and the metallic adhesion layer is greater than Van der Waals adhesion between the material and the first substrate. Optionally, the Van der Waals adhesion between the material and the second substrate is greater than the Van der Waals adhesion between the material and the metallic adhesion layer.

In some examples, the method comprises controlling the Van der Waals adhesion at least in part by controlling a thickness and/or composition of the metallic adhesion layer. In some examples, the method comprises controlling the Van der Waals adhesion at least in part by controlling a temperature of one or more of the substrates. In some examples, the method comprises controlling the Van der Waals adhesion at least in part by controlling a speed of movement of the intermediate substrate.

Optionally, the depositing is a dry process.

In some examples, the support layer of the intermediate substrate is formed of an inorganic material. Optionally, the support layer of the intermediate substrate comprises an oxide or a nitride. In some specific examples, the support layer of the intermediate substrate comprises silicon nitride or silicon dioxide.

In some examples, the metallic adhesion layer comprises at least one of: gold, copper, platinum, chromium, or palladium. In some examples, the flexible intermediate substrate comprises an interfacial layer between the support layer and the metallic adhesion layer. Optionally, the interfacial layer comprising at least one of: tantalum, chromium, titanium, tungsten, niobium, aluminium, or nickel.

In some examples, lifting the material comprises bringing the metallic adhesion layer of the intermediate substrate proximate to the first substrate. Optionally, lifting the material comprises lifting a portion of the first substrate which is bonded to the material and the method further comprises removing the portion of the first substrate from the intermediate substrate before depositing the material on to the second substrate. Optionally, removing the portion of the first substrate is a wet process.

In some examples, depositing the material comprising bringing the metallic adhesion layer of the intermediate substrate proximate to the second substrate.

In some examples, the second substrate comprises an outer layer of a heterostructure having one or more layers. Depositing the material on to the second substrate comprises depositing the material on the outer layer to form another layer of the heterostructure.

In some examples, the method further comprises patterning the support layer in accordance with a predetermined pattern and depositing the metallic adhesion layer on the patterned support layer. In other examples, the method further comprises depositing the metallic adhesion layer on the support layer in accordance with a predetermined pattern. Optionally, lifting the material comprising lifting the material in accordance with the predetermined pattern.

Described herein is a method of forming a heterostructure by removing material from one or more substrates via a flexible intermediate substrate comprising a support layer and metallic adhesion layer. The method comprises lifting a first material from a first area of the one or more substrates with the intermediate substrate, the lifting comprising adhering the first material to the metallic adhesion layer by Van der Waals adhesion between the first material and the metallic adhesion layer. The method comprises lifting a second material from a second area of the one or more substrates with the intermediate substrate, the lifting comprising adhering the second material to the first material by Van der Waals adhesion between the first material and the second material. This method facilitates the simple and quick assembly of 2D heterostructures by Van der Waal adhesion, reducing the cost and assembly time required in the manufacture of devices involving the same.

Optionally, the first area and the second area correspond to areas of a single substrate. Alternatively, the first area and the second area correspond to areas of two different substrates.

Described herein is a flexible substrate for lifting material from a bulk substrate. The flexible substrate can function as a flexible intermediate substrate for performing the above methods. The flexible substrate comprises a support layer and a metallic adhesion layer. Optionally, the support layer comprising a silicon nitride membrane. Optionally, the metallic adhesion layer comprises gold. This substrate facilitates the simple and quick assembly of 2D heterostructures by Van der Waal adhesion, reducing the cost and assembly time required in the manufacture of devices involving the same.

In some examples, the silicon nitride membrane has a thickness of 200 nm to 1000 nm, optionally 500 nm. In some examples, the gold has a thickness between 0.01 nm and 10 nm, optionally between 0.05 nm and 5 nm, optionally between 0.1 nm and 1 nm.

As would be understood by the skilled person in regard to the metallic adhesion layer, thicknesses below an atomic diameter of the constituent metal imply a discontinuous layer of the metal (i.e. a discontinuous dispersion of adatoms or nanoscale islands across the flexible substrate). In other words, to account for films with non-uniform surface morphology, the thickness of the metallic adhesion layer can be the average thickness as measured across a representative surface area.

In some examples, the flexible substrate further comprises an interfacial layer between the support layer and the metallic adhesion layer, interfacial layer comprising at least one of: tantalum, chromium, titanium, tungsten, niobium, aluminium, or nickel.

### LIST OF FIGURES

FIG. 1 (FIGS. 1A, to 1D) provides a schematic illustration of transferring a material from a first substrate to a second substrate via a flexible intermediate substrate comprising a metallic adhesion layer;

FIG. 2 (FIGS. 2A, 2B and 2C) provides a schematic illustration of forming a heterostructure by removing material from one or more substrates via a flexible intermediate substrate comprising a metallic adhesion layer;

FIG. 3 (FIGS. 3A to 3D) schematically illustrates steps of the fabrication of a cantilever-type intermediate substrate;

FIG. 4A illustrates a schematic cross-section of the intermediate substrate and an adhered material, and FIG. 4B shows a cross-sectional high-angle annular dark-field scanning transmission electron image of a fabricated intermediate substrate with an adhered multilayer MoS₂ crystal;

FIG. 5 (FIGS. 5A to 5J) shows an example of the transfer process of FIG. 1;

FIG. 6 provides experimental results for benchmarking of monolayer graphene devices fabricated using a flexible inorganic intermediate substrate in accordance with FIG. 5;

FIGS. 7 and 8 (FIGS. 7A to 7D and FIGS. 8A to 8D) show an example of fabricating encapsulated graphene liquid cells (encapsulated GLCs) by way of the formation process of FIG. 2;

FIG. 9 shows low-magnification Annular Dark Field (ADF) scanning electron microscopy (STEM) images of a GLC manufactured in accordance with FIGS. 7 and 8;

FIG. 10 shows schematic illustrations of example geometries of a flexible intermediate substrate;

FIG. 11 shows schematic illustrations of controlling material shape by patterning the support layer and/or metallic adhesion layer of a flexible intermediate substrate;

FIG. 12 is a flowchart showing operations of transferring a material from a first substrate to a second substrate via a flexible intermediate substrate; and

FIG. 13 is a flowchart showing operations of forming a heterostructure by removing material from one or more substrates via a flexible intermediate substrate;

FIG. 14 (FIGS. 14A to 14G) shows an example of the transfer process of FIG. 1; and

FIG. 15 (FIGS. 15A to 15C) shows an example of the transfer process of FIG. 1.

### DESCRIPTION

Previous approaches to picking up grown or exfoliated 2D crystals used techniques such as thermal release tape and/or chemical etching of a metal adhesion layer. These methods of transfer can lead to contamination of the material/2D crystals when the transfer substrate is removed, as well as destruction of the transfer substrate. Such approaches are therefore single use.

Polymer-assisted transfer approaches for picking up grown or exfoliated 2D crystals can be used successively to assemble multi-layer material stacks or structures. For example, there can be Van der Waals (VdW) delamination from a polymer layer to a substrate. However, the use of polymers reduces the permitted assembly temperature to <180° C. (depending on the glass transition temperature of the chosen polymer), prevents the use of any aggressive cleaning techniques (e.g. most organic solvents swell/dissolve typically used polymers), and does not allow for operation in high or ultra-high vacuum (HV or UHV, respectively) environments (due to degassing of the polymer matrix). There can also be surface contamination of the assembled stack or structure (heterostructure). Achieving 2D heterostructures that behave as artificial crystals, rather than independent materials, requires atomically clean interfaces. Strategies to remove such contamination from already assembled heterostructures include “squeezing” the contamination using a polymer stamp or an AFM tip. While these techniques help with nanofabrication of micrometre-scale proof-of-principle devices, the cleaning process is slow and cannot be easily scaled up to industrial/commercial scales.

Another key consideration is that to date, all Van der Waals (VdW) heterostructures are assembled in air or in inert gases (such as argon or nitrogen, though some atomically thin crystals such as CrI₃ and InSe still degrade when processed in a state-of-the-art inert glove box environment due to the residual oxygen and water), and in low vacuum, which leads to the presence of a variety of volatile species on their surface during the stacking/assembly process. Due to the large interfacial adhesion between 2DMs (which seek to increase the area in atomic contact), when 2DMs are brought together these contaminants tend to aggregate into localized pockets known as blisters or bubbles consisting of air, water, and/or hydrocarbons. This limits the size of homogeneous regions with atomically clean interfaces to the micrometre scale, placing further restrictions on the future development of devices employing VdW heterostructures. This issue can be partially mitigated for some heterostructures, such as graphene/hBN heterostructures, by assembling the structure at elevated temperatures (e.g. 110° C.), which promotes the diffusion of surface contaminants and allows them to escape from the interface between 2D crystals during the transfer process. However, the use of a polymer carrier during the transfer process severely constrains the range of operating environments under which the structures can be assembled (maximum operating temperature depends on the glass transition temperature of the chosen polymer).

It is therefore desirable to provide for alternative assembly of VdW heterostructures. In particular, it has been recognised that a flexible (optionally inorganic) substrate can be used in place of existing polymers, facilitating the fabrication of VdW heterostructures at higher temperatures, and/or under high vacuum conditions. Solvents may also be used prior to deposition of a material onto a target substrate/target heterostructure. Cleaner material interfaces may therefore be provided, allowing for the fabrication of improved VdW heterostructures.

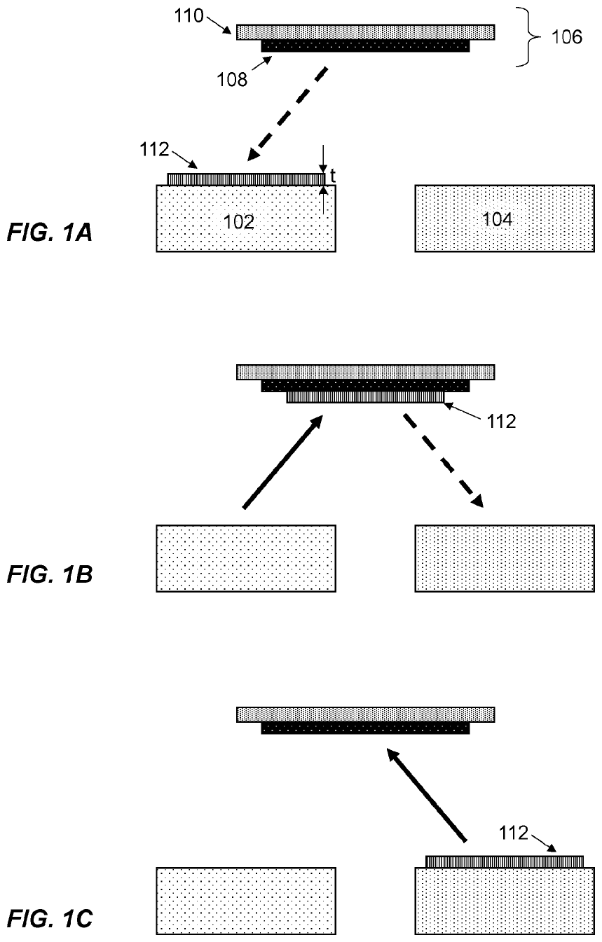

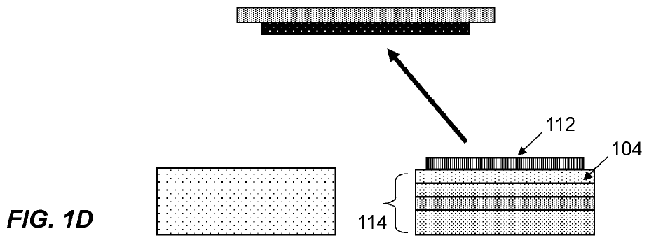

With reference to FIG. 1, a schematic illustration of transferring a material from a first substrate 102 to a second substrate 104 via a flexible intermediate substrate 106 is described. This transferring process can be used in the formation of one or more heterostructures. This non-destructive delamination technique opens a pathway for improved industrial scale fabrication of various VdW heterostructures for both commercial and experimental purposes.

The intermediate substrate 106 comprises a support layer 110 on which a metallic adhesion layer 108 is disposed. The support layer 110 may also be termed a ‘membrane’ herein. The metallic adhesion layer 108 may be formed or otherwise deposited on the support layer 110. In some implementations, the metallic adhesion layer 108 is a metallic film or a metallic surface coating disposed on the support layer 110. One or more intermediate layers (not shown) may be provided between the support layer 110 and the metallic adhesion layer 108.

A material 112 is arranged on the first substrate 102. Material 112 may be one or more exfoliated flakes of material, or may have been otherwise deposited on substrate 102. In some implementations, material 112 may have been grown on substrate 102.

In the following description, material 112 is referred to as a two-dimensional or 2D material. A two-dimensional (2D) material is any low-dimensional material in which the in-plane interatomic interactions are much stronger than those along the stacking direction. 2D materials include crystalline materials consisting of single- or few-layer atoms, as well as multi-layer crystalline materials. 2D materials also include 5 ‘nanosheets’, i.e. a planar material with a nanometre thickness (thickness between 1 nm and 100 nm).

In other words, in the following description the material 112 has a dimension (t) in one spatial direction which is significantly less than dimensions in the other spatial directions in which the material extends. However, depending on the material properties and the degree of Van der Wall adhesion, the transfer process described herein can be applicable to one or more bulk materials as well. Although described in the context of 2DMs, use of the transfer processes is not limited to such materials.

To begin the transfer of material 112, the intermediate substrate 106 is brought proximate to, or into contact with, material 112. This step is not shown, but is indicated by the dashed arrow in FIG. 1A. The proximity between the metallic adhesion layer 108 and material 112 causes the material to lift from the first substrate 102 on to the intermediate substrate 106. The lifting mechanism is provided by Van der Waals 20 adhesion (i.e. adhesion due primarily, or in large part, to Van der Waals forces) between the material 112 and the metallic adhesion layer 108. The material 112 thus adheres to the metallic adhesion layer, and is lifted or removed from the first substrate 102 when the intermediate substrate 106 is moved away from the first substrate 102, as shown in FIG. 1B. The intermediate substrate 106 is moved away from the first 25 substrate 102 by motion of the intermediate substrate and/or motion of the first substrate (there is some relative motion between the two substrates). Depending on the combination of metallic adhesion layer 108, material 112 and substrate 102 (which governs the Van der Waals adhesion between the different layers), the intermediate substrate 106 may not need to be in direct contact with the material 112; rather, the material 112 may ‘jump’ from the substrate 102 to the intermediate substrate 106.

To finish the transfer of material 112, the intermediate substrate 106 comprising the material 112 is brought proximate to, or into contact with, the second substrate 104. This step is not shown, but is indicated by the dashed arrow in FIG. 1B. The proximity between the material 112 and the second substrate causes the material to be deposited onto the second substrate 104 from the intermediate substrate 106. This deposition (or removal) from the intermediate substrate is provided by Van der Waals adhesion (i.e. adhesion due primarily, or in large part, to Van der Waals forces) between the material 112 and the second substrate 104.

The Van der Waals adhesion between the material and the second substrate can be (inherently) greater than the Van der Waals adhesion between the material 112 and the metallic adhesion layer 108, and/or can the adhesion can be otherwise controlled to be greater by varying one or more factors or parameters. The material 112 thus adheres to the second substrate 104 stronger than to the metallic adhesion layer 108, and is deposited or delaminated onto the second substrate 104 when the intermediate substrate 106 is moved away from the second substrate, as shown in FIG. 1C. The intermediate substrate 106 is moved away from the second substrate 104 by motion of the intermediate substrate and/or motion of the second substrate (there is some relative motion between the two substrates).

Depending on the combination of metallic adhesion layer 108, material 112 and substrate 104 (which governs the Van der Waals adhesion between the different layers), the material 112 may not need to be in direct contact with the substrate 104; rather, the material 112 may ‘jump’ from the intermediate substrate 106 to the substrate 104. In this way, the material is delaminated from the metallic adhesion layer of the intermediate substrate onto the second substrate. This delamination occurs without destruction of the flexible intermediate substrate.

In this way, a heterostructure can be built up on the second substrate 104. In some implementations, illustrated in FIG. 1D, the second substrate 104 on which the material 112 is deposited comprises an outer layer of a heterostructure 114 having one or more layers. The depositing of the material 112 on the outer layer 104 thus comprises the forming of another layer of the heterostructure 114. This process can be repeated with different material from one or more substrates to form multiple layers of the heterostructure 114. Such a heterostructure is termed herein a Van der Waals (or VdW) heterostructure, due to the role played by Van der Waals adhesion in its formation.

In some examples, the Van der Waals adhesion between the material and the metallic adhesion layer is greater than any adhesive bonds between the material and the first substrate (for example, greater than Van der Waals adhesion between the material and the first substrate). In these examples, the material 112 is lifted from the first substrate 102 by the metallic adhesion layer 108. This may be the case where the material 112 is an exfoliated crystal or flake. In this way, a “dry” transfer process may be facilitated, where the surface of the 2DMs remain dry throughout the transfer process.

In some other examples, the material 112 can be grown onto the first substrate 102. In such cases, the material 112 tends to be chemically bonded to the substrate, and the adhesive bonds between the material and the surface of the substrate are greater than the Van der Waals adhesion with the metallic adhesion layer. In these examples, lifting the material comprises lifting a portion of the first substrate which is bonded to the material 112, and then removing the portion of the first substrate from the intermediate substrate before depositing the material on to the second substrate. This removal can be by way of a “wet” process (i.e. involving one or more liquids, where 2DMs come in direct contact with liquid). Since the use of a wet process can be incompatible with many polymer based transfer techniques, the intermediate substrate based transfer process described herein allows to extend the transfer functionality/techniques to new materials, and expands the range of VdW heterostructures that may be formed.

Even when one or more wet processes are used on the material 112, or when the material 112 is adhered to or deposited on the intermediate substrate in another manner than the lifting described herein, the depositing process from the intermediate substrate on to the second substrate 104 can still be a dry transfer or deposition process. This “dry” delamination can facilitate the formation of VdW heterostructures 114 from materials which may be damaged by known wet delamination/deposition processes (e.g. processes involving etching). A greater variety of VdW heterostructures may therefore be formed by way of the transfer process described herein.

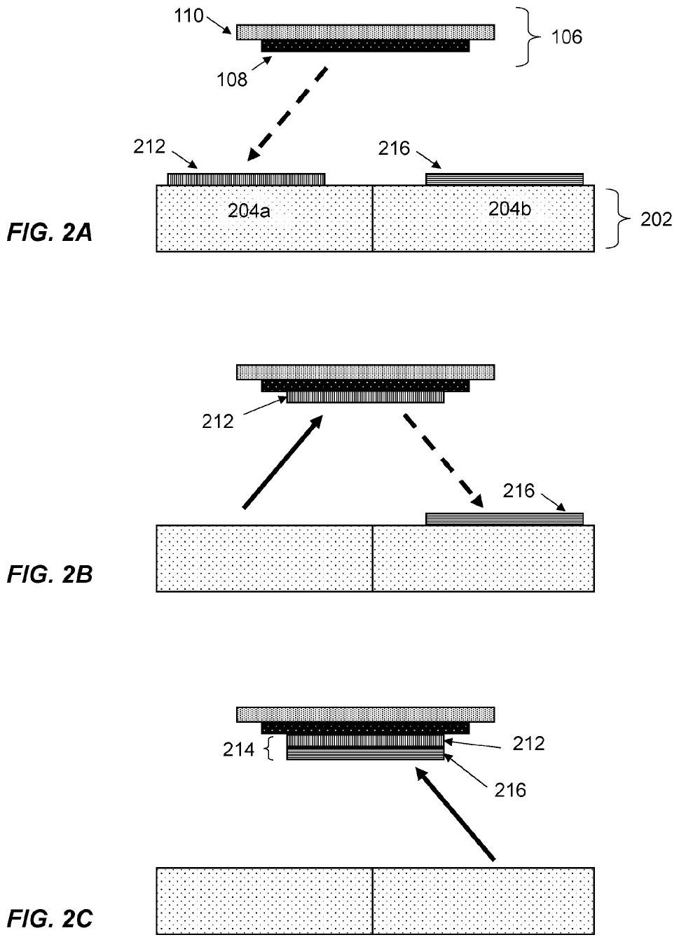

With reference to FIG. 2, a schematic illustration of forming a heterostructure by removing material from one or more substrates 202 via a flexible intermediate substrate 106 is described. Like reference numerals refer to like features of FIG. 1.

The intermediate substrate 106 comprises a support layer 110 on which a metallic adhesion layer 108 is disposed. The metallic adhesion layer 108 may be formed or otherwise deposited on the support layer 110. In some implementations, the metallic adhesion layer 108 is a metallic film or a metallic surface coating disposed on the support layer 110.

A first material 212 is arranged on a first area 204a of the one or more substrates 202. A second material 216 is arranged on a second area 204b of the one or more substrates 102. First material 212 and/or second material 216 may be one or more exfoliated flakes of material, or may have been otherwise deposited on the respective areas 204a, 204b of the one or more substrates 202. In some implementations, first material 212 and/or second material 216 may have been grown on the one or more substrates 202.

In the following description, first material 212 and second material 216 are two-dimensional or 2D materials.

First material 212 and second material 216 can be different materials. Alternatively, they may be the same materials and the adhesion may be controlled by varying one or more factors or parameters. The one or more substrates 202 may comprise a single substrate, where the first 204a and second 204b areas are different areas of a single substrate. In other examples, the first and seconds areas are areas of two different, separate, substrates.

To begin forming the heterostructure on the intermediate substrate, the intermediate substrate 106 is brought proximate to, or into contact with, first material 212. This step is not shown, but is indicated by the dashed arrow in FIG. 2A. The proximity between the metallic adhesion layer 108 and the first material 212 causes the first material to lift from the first area 204a of the one or more substrates 202 on to the intermediate substrate 106. The lifting mechanism is provided by Van der Waals adhesion between the first material 212 and the metallic adhesion layer 108. The material 212 thus adheres to the metallic adhesion layer, and is lifted or removed from the first area 204a when the intermediate substrate 106 is moved away from the first area 204a of the one or more substrates 202, as shown in FIG. 1B. Depending on the combination of substrate, material 212 and metallic adhesion layer 108 (which governs the Van der Waals adhesion between the different layers), the intermediate substrate 106 may not need to be in direct contact with the material 212; rather, the material 212 may ‘jump’ to the intermediate substrate 106.

Next, the intermediate substrate 106 is brought proximate to, or into contact, with second material 216. This step is not shown, but is indicated by the dashed arrow in FIG. 2B. The proximity between the first material 212 and the second material 216 causes the second material to lift from the second area 204b of the one or more substrates 202 on to the intermediate substrate 106. The lifting mechanism is provided by Van der Waals adhesion between the first material 212 and the second material 216. The second material 216 thus adheres to the first material 212, and is lifted or removed from the second area 204b when the intermediate substrate 106 is moved away from the second area 204b of the one or more substrates 202, as shown in FIG. 1C. Depending on the combination of substrate, material 216 and material 212 (which governs the Van der Waals adhesion between the different materials), the intermediate substrate 106 may not need to be in direct contact with the material 216; rather, the material 216 may ‘jump’ to the substrate 106.

In some examples, Van der Waals adhesion between the first material and the metallic adhesion layer is greater than one or more adhesive bonds between the first material 212 and the first area of the one or more substrates 202 and a “dry” transfer process may be facilitated, where the surface of the 2DMs remain dry throughout the lifting process. In other examples, one or more liquids may be used as part of cleaning of the first material after lifting, or to remove portions of the substrate which may be bonded to the first material.

Similarly, in some examples Van der Waals adhesion between the first material and the second material is greater Van der Waals adhesion between the second material 216 and the second area 204b of the one or more substrates 202 and a “dry” transfer process may be facilitated, where the surface of the 2DMs remain dry throughout the lifting process. In other examples, one or more liquids may be used as part of cleaning of the second material after lifting, or to remove portions of the substrate which may be bonded to the second material.

In accordance with the approach of FIG. 2, a heterostructure 214 (or stack of layers of at least two different 2D materials) can be formed or built up on the intermediate substrate 106. The process of FIG. 2 can be repeated (either by repeating the above described steps or using material from one or more other substrates) to form multiple layers of the heterostructure 214. Such a heterostructure is termed herein a Van der Waals (or VdW) heterostructure, due to the role played by Van der Waals adhesion in its formation.

In the approaches described above with respect to FIGS. 1 and 2, the support layer 104 of the intermediate substrate can be formed of an inorganic compound. The term inorganic as used herein means a compound with no carbon-hydrogen (C—H) bonds. The support layer does not include or comprise a polymer (i.e. the support layer can be polymer free). In some specific examples, the support layer 110 comprises an oxide or a nitride. In some more particular examples, the support layer 110 is formed from silicon nitride or silicon dioxide.

The use of a flexible and optionally inorganic substrate/membrane as described herein (e.g. in place of a polymer) can allow the assembly or formation of VdW heterostructures at higher temperatures, as well as avoiding interfacial contamination within the heterostructure during the assembly process. Moreover, the VdW heterostructures can be assembled in aggressive chemical environments, which is not possible with polymer membranes (many solvents are incompatible with polymer-based transfer techniques, since the polymer swells/dissolves in the presence of such solvents). The use of an inorganic substrates in the transfer process therefore broadens the range of materials and operating conditions under which a VdW heterostructure 114, 214 may be formed.

A strength of the respective VdW adhesion between the different materials/layers can be controlled by adjusting one or more factors or parameters. Temperature is one example of such a factor or parameter. In particular, the adhesion can be controlled by changing a temperature of the environment, and thus a temperature of the one or more substrates and/or materials, during the transfer process.

Another factor is the composition and/or thickness of the metallic adhesion layer. The metallic adhesion layer 108 described above with respect to FIGS. 1 and 2 can be formed of one or more different metals. The metals may be deposited in individual layers, and/or as one or more compounds within a single layer. The choice of metal, and the choice of thickness of any given layer, facilitates tuning of the adhesion with 2DMs. Different metallic adhesion layers 108 may therefore be formed for different applications and heterostructures. The characteristics of the metallic adhesion layer can be predetermined for a given application or material/heterostructure.

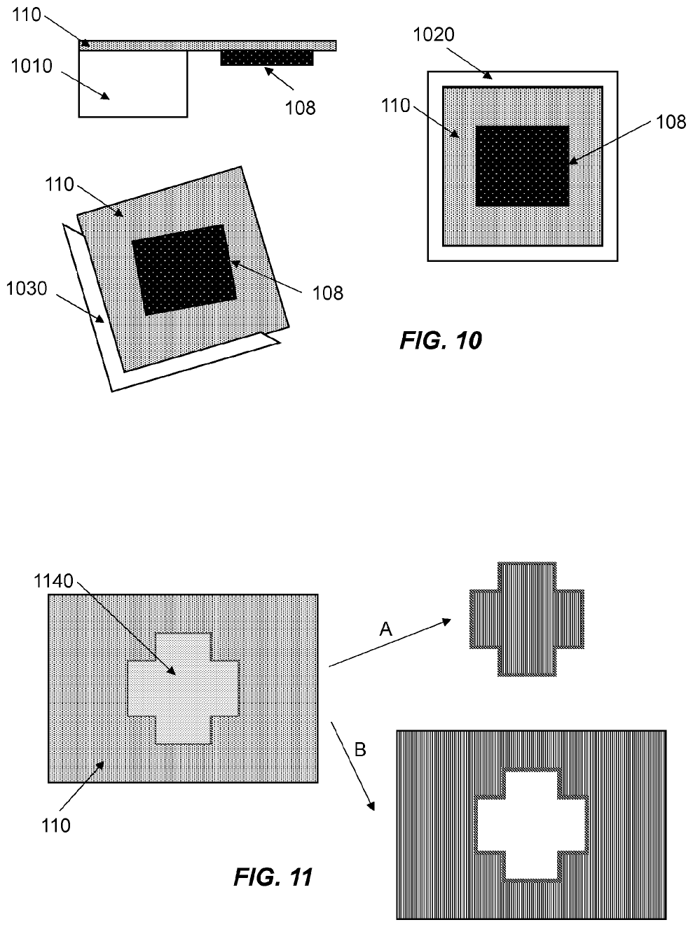

With reference to FIG. 10, the intermediate substrate 106 described with reference to FIGS. 1 and 2 can have any suitable geometry. In some of the specific examples described below, the intermediate substrate is formed as a cantilever or cantilever-type structure, i.e. a flexible portion extending from a bulk material 1010, such that the flexible support layer 110 is fixed at one edge and free at the other edges. However, other arrangements are possible. For example, an external bulk frame 1020 may be provided with a central opening or aperture, wherein the support layer 110 (membrane) extends across the opening and is fixed at all edges. In other examples, a partial frame 1030 may be provided along more than one edge of the support layer 110, but with one or more edges of the support layer 110 free. Schematics of these example intermediate substrate 106 geometries are set out in FIG. 10, but any other suitable arrangement is possible which provides flexibility to the intermediate substrate.

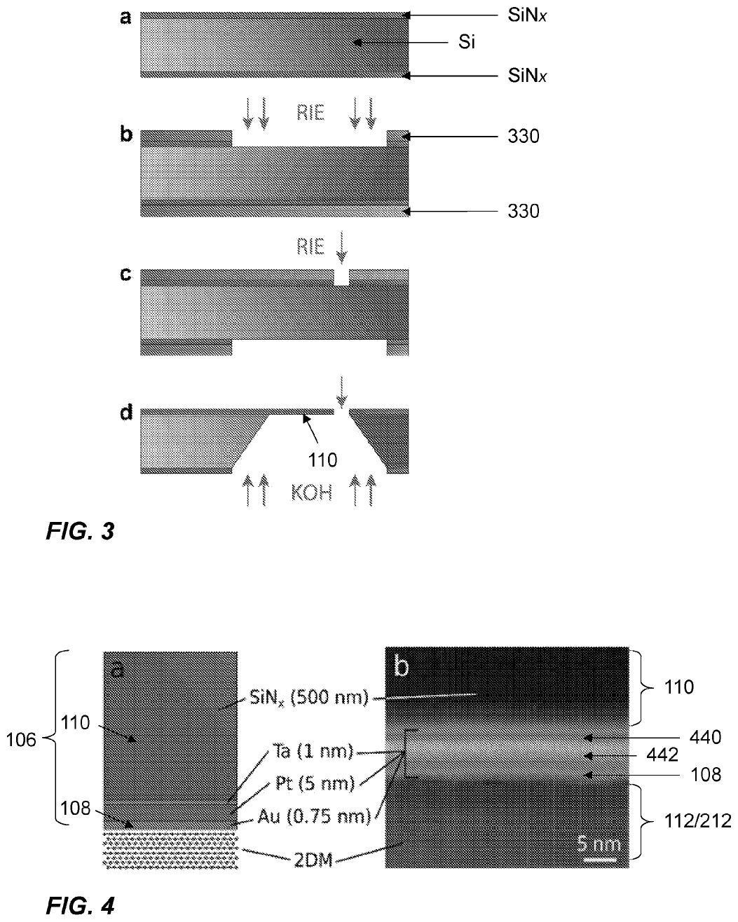

The fabrication of a specific cantilever-type example of the intermediate substrate 106 is now described with reference to FIG. 3. This specific example avoids the use of any organic materials during the VdW assembly process by employing inorganic flexible SiNₓ (silicon nitride) membranes, covered with thin metallic film(s) to form the metallic adhesion layer 108.

For convenient assembly of VdW heterostructures from mechanically exfoliated flakes, SiNₓ membranes were fabricated as a cantilever protruding from a silicon chip. For this example, a wafer-scale process was employed using commercially available silicon (Si) wafers purchased from Inseto UK. These were coated with 500 nm LP-CVD grown SiNₓ on both sides (FIG. 3A).

The cantilevers were fabricated by selectively etching the double-sided 500 nm SiNₓ coated Si wafers shown in FIG. 3A. The nitride layers were patterned into the required cantilever geometry, on both sides, using successive optical lithography and reactive ion etching (RIE) with SF₆ and CHF₃. One side of the wafer is patterned to act as a hard mask for a Si wet etch (FIG. 3B, where the outer layers 330 are a resist etch mask deposited on the SiNₓ). The other side of the wafer is patterned to define the cantilever geometry (FIG. 3C, where the outer layers are resist etch mask 330).

Wet etching was then used to selectively remove the underlying silicon and release the cantilevers. The resist etch mask 330 was removed using oxygen plasma, and the sample was immersed in KOH (aq. 30%, 80° C., ˜7 hours) to release the cantilever by selectively etching away the underlying Si from the area defined by the SiNₓ mask. After rinsing in solvents, the wafer scale cantilever array can be separated for metal coating, i.e. for the formation of metallic adhesion layer 108 described herein (the SiNₓ cantilever portion to be coated can be seen extending from the left hand portion of FIG. 3D). This approach results in transparent, flexible cantilevers, with extremely high thermal and mechanical stability. These cantilevers, consisting of a SiNₓ membrane, represent one specific example of the above-described support layer 110 of the intermediate substrate 106. The support layer in this example has a thickness of 200 nm to 1000 nm, optionally a thickness of 500 nm.

A key factor leading to the current domination of polymer membranes as a transfer mechanism for VdW heterostructures is the good adhesion between the polymer membrane and 2DMs, which allows selective pick up of the 2DM from an original substrate and drop-off to the target wafer. In contrast, bare SiNₓ has poor adhesion to 2DM. To address this poor adhesion, the above-described cantilevers 110 are coated with a metallic adhesion layer 108.

It will be understood that any suitable metallic adhesion layer may be formed. The metallic adhesion layer can comprise at least one of: gold, copper, platinum, chromium, or palladium. The metallic adhesion layer can be any suitable thickness. The metallic adhesion layer can have a thickness between 0.01 nm and 10 nm, optionally between 0.05 nm and 5 nm, optionally between 0.1 nm and 1 nm, optionally between 0.3 nm and 1 nm. The Van der Waals adhesion between materials to be lifted/deposited and the metallic adhesion layer 108 can be controlled at least in part by controlling a thickness and/or composition of the metallic adhesion layer. The thickness and/or composition can be predetermined for a given application or heterostructure design, and is an example of the factors or parameters that can be controlled or adjusted to change the degree or strength of VdW adhesion.

In this specific example, the cantilever support layer 110 is coated with a tri-metal stack consisting of: an optional interfacial layer 440 of 1 nm tantalum, Ta; an optional intermediary layer 442 of 5 nm of platinum, Pt; and a metallic adhesion layer 108 of 0.1 nm to 1 nm of gold, Au (see FIGS. 4A and 4B). In particular, FIG. 4A illustrates a schematic cross-section of the intermediate substrate 106 and an adhered material 112/212, and FIG. 4B shows a cross-sectional high-angle annular dark-field scanning transmission electron image of a fabricated intermediate substrate 106 (cantilever-type) with an adhered multilayer MoS₂ crystal (example of material 112/212).

Au has a high adhesion to 2DMs, and adjusting its thickness (and therefore the area coverage) allows tuning of the surface adhesion of the metallic adhesion layer 108 for a specific application. For instance, when picking up hBN mechanically exfoliated onto SiO₂, a 0.1 nm Au layer does not provide sufficient adhesion to guarantee the transfer, while 1 nm will guarantee the pick-up (though the adhesion for a 1 nm Au layer is too high, as the assembled stack cannot be later released onto a target wafer without damage and delamination). Experimentally, it has been found that the best adhesion for picking up exfoliated flakes from a SiO₂ substrate is a gold layer of thickness 0.65 nm Au.

The optional interfacial layer 440 serves to help adhere the metallic adhesion layer 108 (and optionally the intermediary layer 442) to the support layer 110. Any suitable material can be used as the interfacial layer 440. The particular material can be chosen to provide the desired adherence between the specific materials of the support layer 110 and the metallic adhesion layer 108. In some examples, the interfacial layer comprises at least one of: tantalum, chromium, titanium, tungsten, niobium, aluminium, or nickel. In some examples, no interfacial layer 440 is provided.

The optional intermediary layer 442 can be used to adjust for variable cantilever roughness (i.e. smoothing the surface prior to formation of the metallic adhesion layer 108 and providing better reproducibility between different SiNₓ batches). A Pt intermediary layer 442 can also facilitate catalytic decomposition of mobile surface hydrocarbons when heated. In this example, a Pt intermediary layer is sputtered onto the interfacial layer 440, but any suitable deposition process can be used. Any suitable intermediary layer 442 can be used, depending on the application. In some examples, no intermediary layer 442 is provided.

A freshly (metal) coated cantilever (intermediate substrate 106) is then affixed to a commercially-available 2DM transfer micromanipulator system (Graphene Industries) and is used to sequentially pick-up exfoliated crystals in a similar manner to polymer-based methods, in accordance with the process described above with reference to FIGS. 1 and 2. The intermediate substrate 106 can be used repeatedly, without any damage to the underlying cantilever structure. The flexible nature of the cantilever allows accurate control of the lamination (lifting) process and the delamination (depositing) process, improving the transfer process.

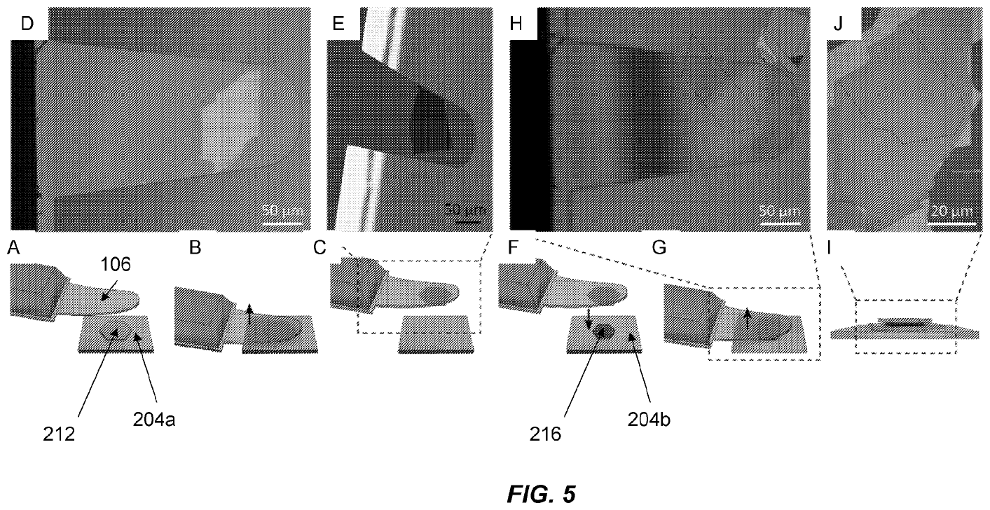

An example transfer process using the intermediate substrate 106 of FIGS. 3 and 4 is described further with reference to FIG. 5, which illustrates assembly of an archetypal hexagonal boron nitride (hBN)/graphene/hBN heterostructure from 2D crystals mechanically exfoliated on a Si/SiO₂ wafer or substrate. This approach is an example of the process of FIG. 2, where a heterostructure 214 is formed on the intermediate substrate 106.

Firstly, the cantilever intermediate support 106 is aligned above the first target material 212 (here a first hBN crystal), as shown in FIG. 5A, and lowered with 20° tilt until contact is made (FIG. 5B). The intermediate substrate 106 is brought into contact with first material 212. The environmental operating temperature is between 120-150° C. in this example. After a few seconds the cantilever 106 is slowly raised, delaminating the flake from a first area 204a of a Si/SiO₂ substrate (FIG. 5C). Optical (FIG. 5D) and SEM (FIG. 5E) micrographs show the resulting cantilever 106 with thick (˜40 nm) hBN crystals 112/212 adhering to it. The adhesion can be controlled in part by controlling a speed of movement of the intermediate substrate during the lowering and raising operations. The speed of movement is another example of a factor or parameter that can control the strength of VdW adhesion.

In other words, the proximity between the metallic adhesion layer 108 and the first material 212 causes the first material to lift from the first area 204a on to the intermediate substrate 106. The lifting mechanism is provided by Van der Waals adhesion (i.e. adhesion due primarily, or in large part, to Van der Waals forces) between the first material 212 and the metallic adhesion layer 108. The material 212 thus adheres to the metallic adhesion layer, and is lifted or removed from the first area 204a when the intermediate substrate 106 is moved away from the first area 204a. It has been found that with a correctly selected gold thickness, the reproducibility of this lifting process is better than 95% (based on over 150 operations performed).

Secondly, the cantilever intermediate support 106 is aligned above the second target material 216 (here a graphene crystal) on a second area 204b of an (optionally different) Si/SiO₂ substrate, as shown in FIG. 5F, and lowered with 20° tilt until contact is made (FIG. 5G). The intermediate substrate 106 is brought into contact with second material 216. Optical micrograph (FIG. 5H) shows the cantilever being in contact with the graphene (edges highlighted with dashed line) on the substrate. After a few seconds the cantilever 106 is slowly raised from a second area 204b, delaminating the graphene from the Si/SiO₂ substrate. The adhesion can be controlled in part by controlling a speed of movement of the intermediate substrate during the lowering and raising operations.

In other words, the proximity between the first material 212 and the second material 216 causes the second material to lift from the second area 204b of the Si/SiO₂ substrate and on to the intermediate substrate 106. The lifting mechanism is provided by Van der Waals adhesion between the first material 212 and the second material 216. The second material 216 thus adheres to the first material 212, and is lifted or removed from the second area 204b when the intermediate substrate 106 is raised to form a heterostructure 214 on the intermediate substrate 106.

In this example, Van der Waals adhesion between the first material hBN and the metallic adhesion layer 108 is greater than Van der Waals adhesion between the first material 212 and the Si/SiO₂ substrate, and the hBN crystal can be lifted from the substrate by way of a dry transfer process. Moreover, Van der Waals adhesion between the first material, hBN, and the second material, graphene, is greater than Van der Waals adhesion between the second material 216 and the second area 204b of the substrate, and the graphene can be lifted from the Si/SiO₂ substrate by way of a dry transfer process. For other substrates/materials, one or more wet processes may be required to clean the first and/or second materials prior to deposition of the assembled stack 214 on a target substrate.

With further reference to FIG. 5, the hBN/graphene stack 214 is then deposited (removed) from the intermediate substrate 106 onto a bottom hBN crystal (FIG. 5I) to form a heterostructure on a target substrate. FIG. 5J shows an optical micrograph of the finished heterostructure stack on an oxidised silicon Si/SiO₂ wafer indicating large uniform areas. The graphene layer 216 is shown by the dashed lines. It can be seen that the heterostructure has a large, clean, bubble-free region (larger than 25 μm×40 μm) despite a very fast (e.g. in the range of seconds) lamination/delamination time. This clean region is achieved by avoiding contact with polymers during the whole process, as well as sample heating during the transfer process (150° C. top hBN, 120° C. graphene and 230° C. bottom hBN). In addition, improved positioning accuracy was observed compared to known polymer methods, with the positioning accuracy limited only by the optical resolution of the microscope used (better than 400 nm), since the inorganic SiNₓ membrane support layer 110 displays negligible drift and warping when heated and compressed.

For other devices, operating temperatures of up to 350° C. have been tested and the complete disappearance of hydrocarbon bubbles was observed. However, it is noted that the use of temperatures above 150° C. during monolayer graphene pick-up from Si/SiO₂ wafer can be detrimental, due to the formation of microcracks in the monolayer graphene (possibly due to adhesion of graphene to the wafer and strain caused by differential thermal expansion with the Si/SiO₂ wafer).

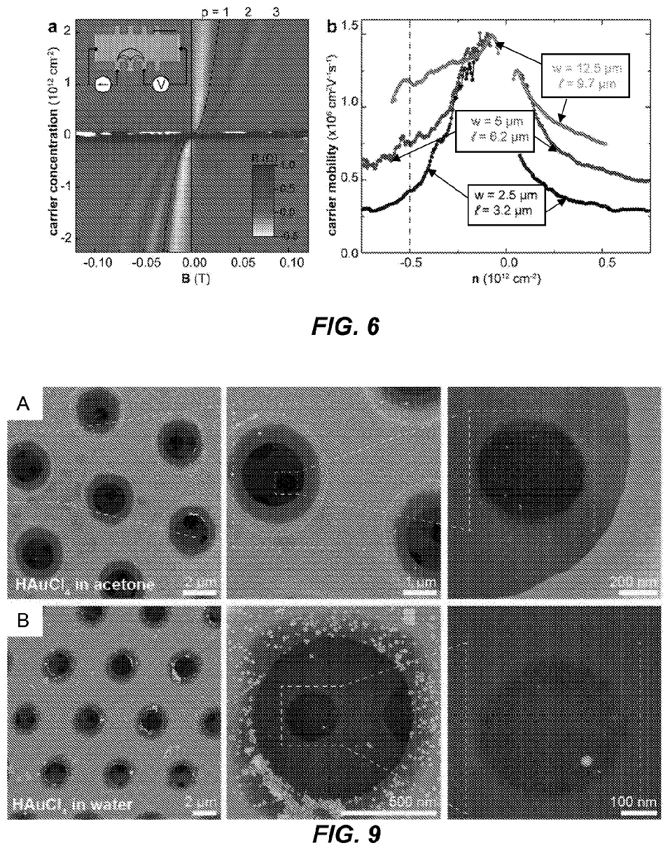

To characterize the quality of the encapsulated graphene material 216, electronic transport benchmarking of monolayer graphene devices (fabricated using the inorganic flexible substrate transfer technique discussed with reference to FIG. 5) was performed and the results are provided in FIG. 6.

For the specific graphene device shown in the micrographs of FIG. 5, magnetic focusing experiments were employed, whereby electrons injected from one contact are magnetically deflected into another contact (collector) and the corresponding voltage is measured. The inset of FIG. 6A shows an optical micrograph of the device and the measurement circuit. In particular, the transfer resistance (R) for these magnetic focusing experiences was measured as a function of carrier density and magnetic field (B), at a temperature of 5K.

The transfer resistance measured in this configuration is presented in FIG. 6A, in which multiple focusing peaks can be observed, with the first peak corresponding to direct transfer of electrons from the injector to the collector (p=1), and subsequent peaks (p=2, 3) corresponding to electrons which scatter from the edge of the device before reaching the collector. Magnetic focusing peaks occur when the magnetic field is sufficient to divert the injected electrons into the collector. The curved lines illustrate the electron trajectories for each of the focusing peaks p=1, 2 and 3. This data clearly indicates ballistic propagation of charge carriers over the length of the curved trajectory, which for this device is 20 μm and corresponds to the carrier mobility of 2·10⁶ cm⁻²V⁻¹s⁻¹ (at n=0.5·10¹² cm⁻²).

Secondly, different multi-terminal hall-bar devices were fabricated, and then studied at a temperature of 5K. In particular, carrier mobility was studied for 3 different graphene devices with various hall-bar dimensions, each graphene device fabricated in accordance with the process of FIG. 5. One dimensional contacts were then fabricated on each graphene device using electron beam lithography (EBL), followed by metallization and lift-off using heated acetone. A second EBL step followed by RIE etching (CHF₃+O₂) was used to shape the stack into a hall bar geometry. Solid lines in FIG. 6B show Drude model fitting using mean free path (l) as a parameter. Extracted values of the mean free path l agree well with the dimensions (w) of the studied devices (shown for each device in FIG. 6B). Field-effect mobility (μ) was also studied in the 3 devices. For all samples, a mean free path (l) was found to be saturated due to the physical size of the device, and the field-effect mobility was found to reach well over 10⁶ cm⁻²V⁻¹s⁻¹ at low carrier concentrations, and to display characteristic dependence of:

$$μ = l ( 2 e / h ) \sqrt{π / n} ,$$

where e is the electron charge, h is the Planck constant, n is the number density of electron gas.

The above-described transfer process has also been assessed for use with a variety of organic solvents, which are incompatible with traditional polymer transfer method (e.g. solvents such as toluene, chlorobenzene, cyclohexane, chloroform, various ketones, etc.). It was found that additional force may be required to make contact between the intermediate substrate 106 and a substrate as compared to the process described above with respect to FIG. 5 (potentially due to the formation of a solvent shell around the solid surfaces, particularly for polar solvents), but transfer of material between substrates by way of Van der Waals adhesion was achieved with an intermediate substrate 106 as described herein.

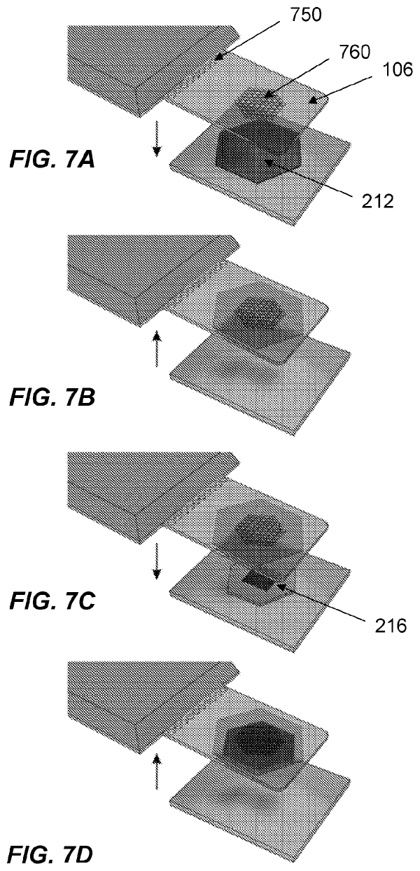

A specific use case of fabricating graphene liquid cells (graphene LCs or GLCs) for TEM investigation by exploiting the ability of VdW heterostructures to trap material in pockets is now described, with reference to FIG. 7.

TEM LCs employ two electron-transparent, but impermeable, membranes to contain a liquid sample, preventing it from evaporating under the high voltage (HV) environment of the electron microscope. The use of such membranes enables imaging of the contained (or encapsulated) liquid sample(s). Graphene membranes have advantages over traditionally used SiNₓ membranes, in particular the ability to form significantly thinner windows. Commercially available silicon nitride windows are typically 20-50 nm thick, whilst GLCs with graphene thicknesses of a few nm have been demonstrated; the thinner membranes/windows limit electron scattering and improve resolution, allowing atomic resolution imaging of liquid samples.

The use of the intermediate substrate 106 in the formation of the GLC avoids the use of polymers, which generate additional contamination on the windows and constrain the choice of liquid that can be sealed within the GLC (since many organic solvents, such as acetone, dissolve or swell the polymer membranes). Moreover, unlike with polymer-based assembly techniques, heating of the solution is not required during the GCL fabrication, which prevents unintended chemical changes prior to the TEM experiments.

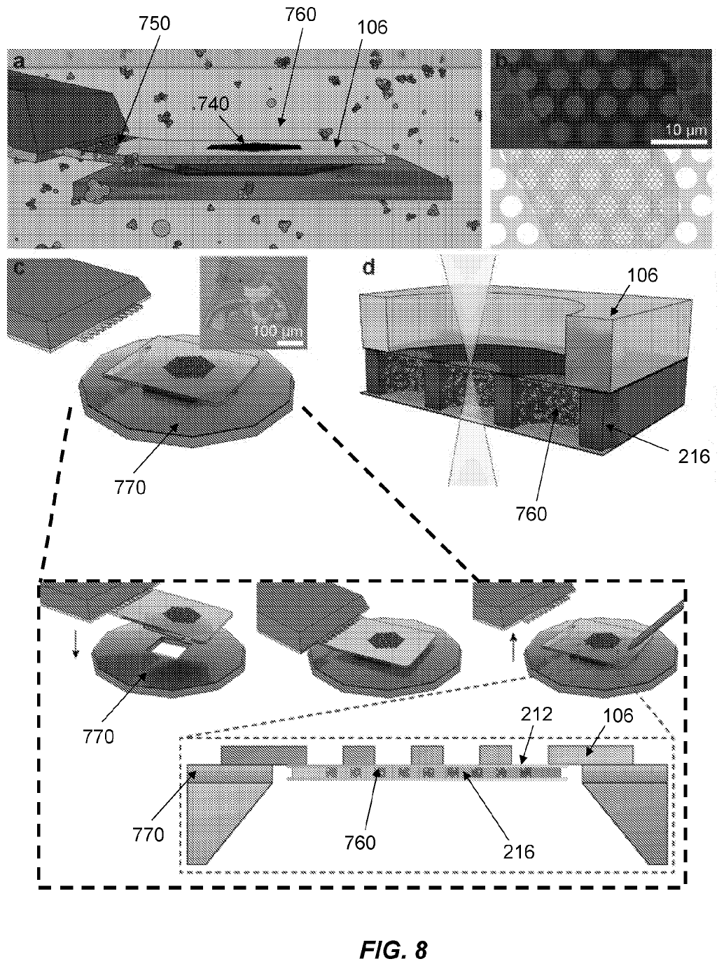

The fabrication process for the GLC (example of stack 214) is described with reference to FIGS. 7 and 8. Firstly, the cantilever support layer 110 is pre-patterned with 3 μm diameter holes 740, as well as a perforated line 750 near the cantilever base (shown in FIG. 7A). For fabrication of suspended samples (as in the case of GLC), the stack 214 does not need to be separated from the cantilevered intermediate substrate 106. Therefore, the support layer 110 is coated with 1 nm Au layer metallic adhesion layer 108—this thickness increases the flake adhesion and ease of initial pickup.

Intermediate substrate 106 is shown in FIG. 7A with the patterned holes 740, 750 of the support layer.

GLC assembly is carried out by picking up a top few-layer graphene (FLG) window (first material 212) on the cantilever. Optimal thicknesses for the FLG windows has been found to be in the 3-10 layer range, which provides exceptional stability under electron illumination without causing sufficient scattering to degrade the achieved imaging resolution. The metal-coated cantilever (intermediate substrate 106) is aligned so that the array of holes in the cantilever are directly over the target FLG flake, and then the cantilever is lowered into the flake at an elevated temperature of approximately 110° C. (FIG. 7A). After a few seconds in contact, the cantilever is raised, peeling away the flake from the substrate (FIG. 7B).

A 20-30 nm thick hBN spacer (second material 216) is pre-patterned with an array of holes or wells, in this example 400-600 nm diameter wells. In particular, circular wells are patterned into the hBN spacer using electron beam lithography to pattern a polymer etch mask, followed by RIE (using CHF₃/O₂) to selectively remove hBN. The polymer etch mask is then removed by cleaning in solvents and subsequently annealing. The thickness of the hBN spacer layer can be chosen depending on experimental requirements, although the size of the wells needs to be adjusted to the layer thickness, as the windows can collapse if the wells' aspect ratio is too low. The hBN spacer (second material 216) is adhered to the FLG window first material. In particular, the cantilever is aligned over the patterned hBN so that the cavities in the hBN overlap with the holes in the cantilever (FIG. 7C), then the cantilever with the FLG flake is brought into contact with the patterned hBN flake (again, at approximately 110° C.). The cantilever is then slowly raised, delaminating the hBN from the substrate (FIG. 7D).

With reference to FIG. 8A, the cantilever-type intermediate substrate 106 containing the top FLG 212 and the patterned hBN 216 are aligned over the bottom FLG and brought near to contact. Then the whole system is submerged in the liquid 760 that is to be encapsulated within the graphene FLGs. In this example, the cantilever 106 with the top FLG and hBN is submerged in a liquid solution 760 of 25 μM HAuCl₄ in acetone, and brought into contact with the bottom hBN to seal the liquid cell (FIG. 8A), therefore trapping liquid within the cavities in the hBN and forming the sealed GLC.

In other words, encapsulation of liquid 760 within the wells or voids etched into the hBN is achieved during the pick-up of the bottom graphene from within the solution 760. Submerging the cantilever in the liquid being encapsulated provides increased control over the concentration within the GLC (as compared to adding a small aliquot of liquid before sealing and drying the GLC). Moreover, due to the volatile nature of the acetone the transfer is done at room temperature, as any heat applied during the transfer would exaggerate acetone evaporation. The transfer process described herein thus enables transfer of heat-sensitive liquid specimens. The range of liquid samples which can be imaged at atomic resolution is therefore increased. The described transfer process can also increase the transfer yield and reduce fabrication time for a GLC from approximately 3 days to around 20 minutes.

The imaging area available for the GLC liquid cell TEM imaging corresponds to the area of overlap of the bottom FLG, cavity in the hBN 216, top FLG 212 and holes 740 in the cantilever. The cantilever is lifted slowly out of the liquid 760 so that the bottom FLG delaminates from the substrate and the entire sealed GLC is adhered onto the cantilever 106 by VdW adhesion. The top panel of FIG. 8B shows an optical micrograph of the assembled liquid cell 214 on the cantilever (intermediate substrate 106). The lower panel of FIG. 8B shows the arrangement of voids in the hBN spacer (small holes) overlaid on the patterned cantilever (large holes).

To facilitate transfer to the TEM, the cantilever is then lowered onto a TEM compatible support 770—in this example, a nitride coated silicon chip of approximately circular shape (3 mm diameter), with a central through hole larger than the array of holes in the cantilever 106, but smaller than the width of the cantilever. In this example, the through hole is 60 μm. The TEM support is also optionally coated with Au (not shown) to promote the adhesion of the cantilever to the support.

With reference to FIG. 8C, the cantilever and heterostructure 214 is then deposited over the 60 μm through hole in the TEM compatible support: the cantilever is aligned so that the holes overlay the large through hole in the support 770, then the cantilever is lowered until in contact, held in place (for example with a micromanipulator tip), and then the silicon chip/wafer the cantilever was attached to is removed, fracturing the silicon nitride layer (support layer 110) along the perforation 750 (see dashed box of FIG. 8C). This detachment of the intermediate substrate over the opening in the target substrate forms the TEM grid. The inset of FIG. 8C shows an optical micrograph of the final structure (resolution 100 μm). FIG. 8C (within the dashed lines) and FIG. 8D illustrate schematic cross-sections of the resulting GLC heterostructure 214 on the TEM support 770. The first material 212 is arranged on the intermediate substrate 106.

With reference to FIG. 9, low-magnification Annular Dark Field (ADF) scanning electron microscopy (STEM) images are shown, which compare a GLC manufactured in accordance with FIG. 6 to corresponding cells encapsulating 25 μM HAuCl₄ in water. In particular, FIG. 9A shows liquid cell structures for 25 μM HAuCl₄ in acetone, and FIG. 9B shows liquid cell structures for 25 μM HAuCl₄ in water. ADF-STEM images 30 were acquired using an aberration corrected JEOL GrandARM 300F operated at 80 kV, at an original resolution of 2048×2048 and with a pixel dwell time of 20 μs. It can be seen that there is a difference between the gold precipitated from acetone, compared to that from aqueous solution. Whereas aqueous solutions of HAuCl₄ are unstable and lead to precipitation of large Au nanoparticles (large Au particles precipitated from solution during transfer are clearly visible in the aqueous cells of FIG. 9B), the acetone solution results in a large number of individual gold atoms deposited onto the FLG membrane. The optimised design and high purity of the samples, manufactured using the inorganic intermediate substrate 106 described herein, enables direct visualisation of single Au atoms in liquid by TEM imaging.

In some examples, described with reference to FIG. 11, patterning of the support layer 110 and/or metallic adhesion layer 108 can be used to affect a shape and/or size of the material (112, 212, 216) being lifted from a substrate. In particular, lifting the material comprising lifting the material in accordance with the predetermined pattern. Any suitable pattern can be used to control the shape of the material, and the size/shape of the pattern can be predetermined, based on a desired use of the fabricated heterostructure and/or the material(s) being lifted. The use of such patterning can facilitate fabrication of a wider range of VdW heterostructures 114, 214. In the following, patterning of the support layer or the metallic adhesion layer is discussed, but it will be understood that both may be patterned in some examples (either with the same or different patterns).

With reference to FIG. 11, in some implementations the support layer 110 can be patterned in accordance with a predetermined pattern 1140. Pattern 1140 (here a cross shape, but any pattern can be used) can be formed in relief on support layer 110 or in counter-relief (intaglio). The metallic adhesion layer 108 subsequently formed or deposited on the patterned support layer will follow the contours of the patterned support layer. Due to the resulting variance in the surface of the metallic adhesion layer, adhesion between the intermediate substrate 106 will vary across the substrate in dependence on the pattern 1140.

In example A, the pattern 1140 is in relief, and the material 112 is lifted in the same pattern as 1140. In example B, the pattern is intaglio, and the material 112 is lifted onto the metal adhesion layer in all places expect where the pattern 1140 is formed (since the adhesion is weaker in this area due to a greater distance between the material 112 and the surface of the metal adhesion layer). In other words, the material can be lifted in dependence on the shape of the pattern 1140, and the shape of the lifted material 112 can be thus controlled.

In other examples, the support layer 110 is not patterned and instead pattern 1140 is formed by application of the metallic adhesion layer 108 (not shown in FIG. 11). The metallic adhesion layer is deposited on the support layer in accordance with a predetermined pattern. For example, the metallic adhesion layer 108 can be formed on the support layer in pattern 1140, or pattern 1140 can represent the area of the support layer on which there is no metallic adhesion layer 108. In the same manner as above, when the metallic adhesion layer is formed in pattern 1140, the material 112 is lifted in the same pattern as 1140 (example A). Alternatively, when the pattern 1140 is an absence of metallic adhesion layer 108, the material 112 is lifted onto the metal adhesion layer in all places expect where the pattern 1140 is formed (example B).

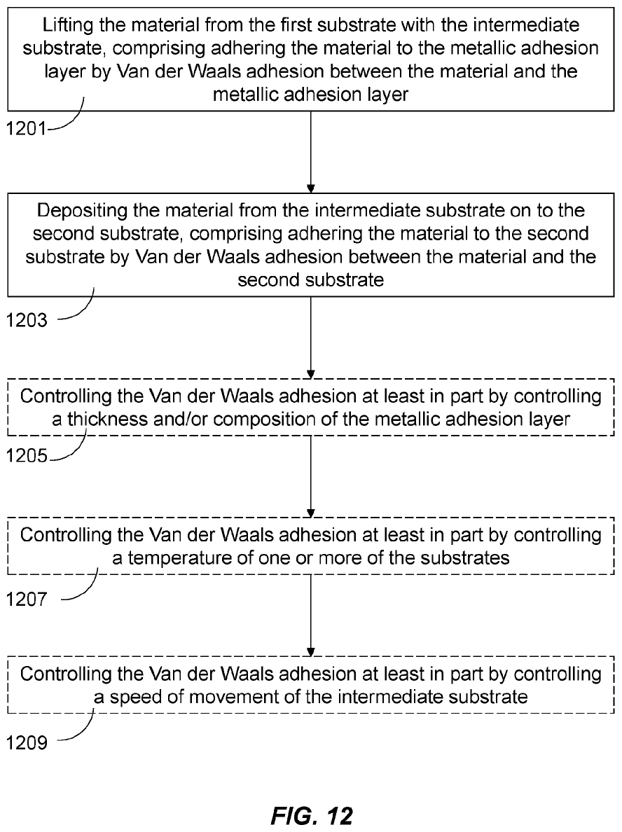

With reference to FIG. 12, operations for transferring a material from a first substrate to a second substrate via a flexible intermediate substrate comprising a support layer and a metallic adhesion layer are described. The operations of FIG. 12 reflect the transfer process discussed above with respect to FIG. 1.

Operation 1201 comprises lifting the material from the first substrate with the intermediate substrate, the lifting comprising adhering the material to the metallic adhesion layer by Van der Waals adhesion between the material and the metallic adhesion layer.

Operation 1203 comprises depositing the material from the intermediate substrate on to the second substrate, the depositing comprising adhering the material to the second substrate by Van der Waals adhesion between the material and the second substrate.

To facilitate the transfer, the Van der Waals adhesion between the material and the second substrate can be greater than the VdW adhesion between the material and the metallic adhesion layer. The adhesion may be inherently greater, due to the nature of the material(s), and/or one or more factors or parameters may be controlled to control or vary the adhesion.

Optionally, operation 1205 comprises controlling the VdW adhesion at least in part by controlling a thickness and/or composition of the metallic adhesion layer. Optionally, operation 1207 comprises controlling the VdW adhesion at least in part by controlling a temperature of one or more of the substrates. Optionally, operation 1209 comprises comprising controlling the VdW adhesion at least in part by controlling a speed of movement of the intermediate substrate. Operations 1205, 1207 and 1209 are optional operations, and may be employed in any suitable combination to control VdW adhesion(s) and facilitate operations 1201 and 1203. Any other method or approach for controlling VdW adhesion may also be used in conjunction with the intermediate substrate described herein.

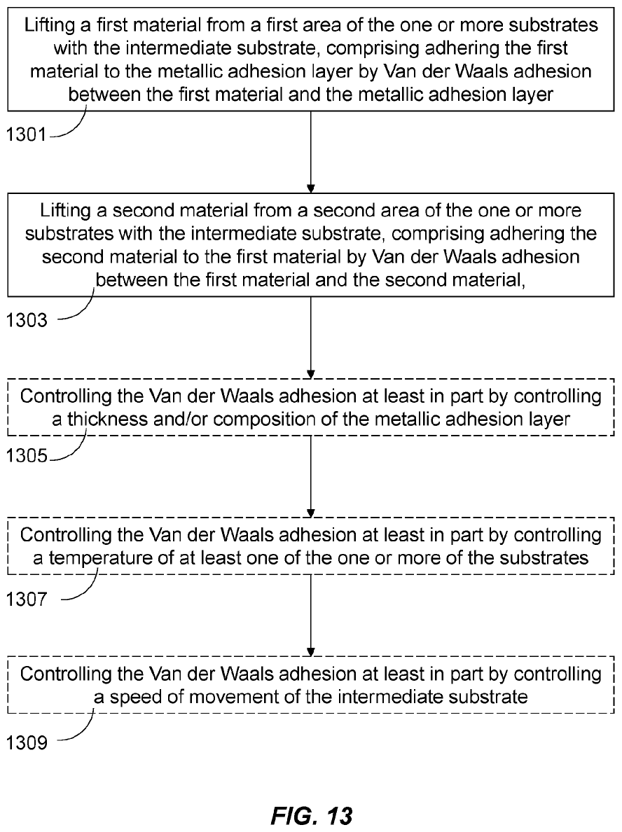

With reference to FIG. 13, operations for forming a heterostructure by removing material from one or more substrates via a flexible intermediate substrate comprising a support layer and metallic adhesion layer are described. The operations of FIG. 12 reflect the formation/fabrication process discussed above with respect to FIG. 2.

Operation 1301 comprises lifting a first material from a first area of the one or more substrates with the intermediate substrate, the lifting comprising adhering the first material to the metallic adhesion layer by VdW adhesion between the first material and the metallic adhesion layer.

Operation 1303 comprises lifting a second material from a second area of the one or more substrates with the intermediate substrate, the lifting comprising adhering the second material to the first material by VdW adhesion between the first material and the second material.

To facilitate the formation/fabrication process, the first and second materials can be different. In this way, the adhesion may be different, due to the different nature of the material(s). In other examples, the first and second materials may be the same. In either case, one or more factors or parameters may be controlled to control or vary the adhesion. Optionally, operation 1305 comprises controlling the VdW adhesion at least in part by controlling a thickness and/or composition of the metallic adhesion layer. Optionally, operation 1307 comprises controlling the VdW adhesion at least in part by controlling a temperature of at least one of the one or more substrates. Optionally, operation 1309 comprises comprising controlling the VdW adhesion at least in part by controlling a speed of movement of the intermediate substrate. Operations 1305, 1307 and 1309 are optional operations, and may be employed in any suitable combination to control VdW adhesion(s) and facilitate operations 1301 and 1303. Any other method or approach for controlling VdW adhesion may also be used in conjunction with the intermediate substrate described herein.

An (optionally completely inorganic) transfer process for 2DMs has been described. The process works both at room temperature (for heat sensitive samples) and at high temperatures (>600° C.), as well as in an ultra-high vacuum, and enables reliable fabrication of VdW heterostructures 114, 214 which have large bubble-free areas up to 100×100 μm² and exhibit excellent electronic transport properties (studied devices routinely demonstrate carrier mobilities higher than 1.0×10⁶ cm²V⁻¹s⁻¹ at 5K). In this way, 2D heterostructures with perfect interfaces (free from interlayer contamination) and correspondingly excellent electronic behaviour can be produced.

The described transfer technique is simple and quick, reducing the cost and assembly time for VdW heterostructures, and enables high-quality transfers of 2DMs in only a few seconds per pickup (liquid cells can be fabricated in 20 minutes, as opposed to previous methods that can take several days). The size of the heterostructures 114, 214 is limited only by the size of the 2DMs themselves. Furthermore, due to the chemical inertness of the materials used, the technique is suitable for aggressive industrial chemical environments. In addition, by using a cantilever patterned with through holes (e.g. a patterned intermediate substrate 106) it is possible to fabricate suspended samples for a variety of mechanical, optical and permeation studies.

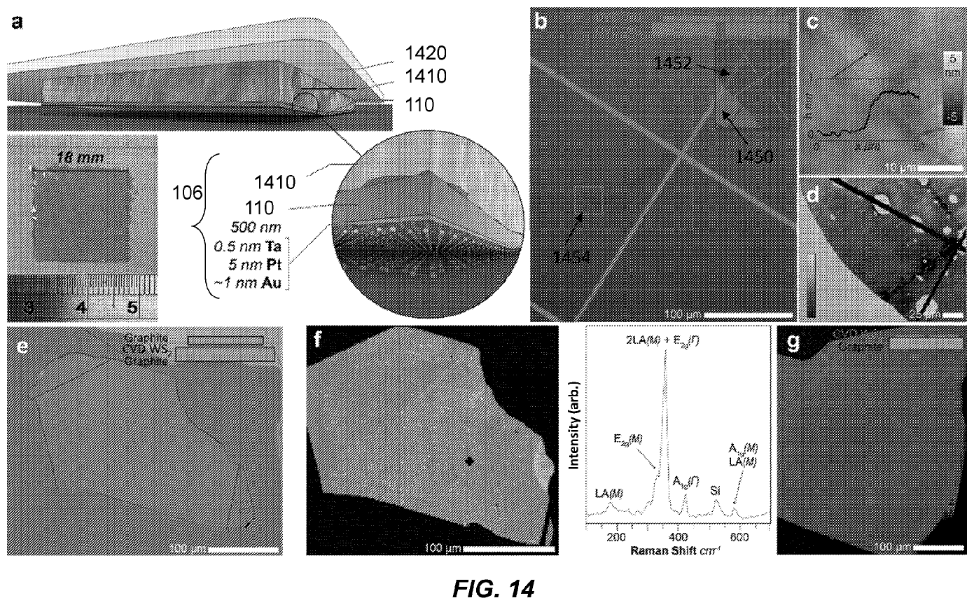

At the microscopic level, the support layer 110 described herein itself exhibits the necessary flexibility required for the delamination or deposition process (e.g. acts as a flexible membrane). However, as the size of the 2DMS used to form heterostructures 114, 214 increases, the support layer 110 correspondingly increases in size. Above a surface area on the order of millimetres squared, the support layer becomes fragile, and prone to breaking. Although a thicker support layer may be used as the surface area is increased, increasing the thickness can reduce the innate or inherent flexibility of the support layer 110. Moreover, the thickness of the support layer is limited by technical factors, such as growth of the support layer and build-up of internal strain in silicon nitride. When manipulating larger 2DMS (when a larger surface area of material needs to be transferred), an additional polymer layer 1410 may therefore be provided, as shown in FIG. 14, to provide the desired flexibility/conformity for the flexible intermediate substrate 106. Such a layer of polymer can also be termed a “stamp”. The polymer layer 1410 provides conformal re-enforcement of the support layer to achieve the same flexibility and structural integrity over large surface areas as is achieved using the above described, un-reinforced, cantilever arrangement over smaller surface areas.

With reference to the schematic diagram of FIG. 14a, a polymer layer 1410 is provided on one side of the support layer 110. The support layer 110 is provided between the polymer layer 1410 and the metallic adhesion layer 108 (here shown as a layer of gold, Au). In this example, there is also shown an optional interfacial layer 440 of tantalum (Ta) and an optional intermediary layer 442 of Pt. In other words, there is provided a flexible substrate 106 for depositing material onto a bulk substrate, the flexible substrate comprising: a support layer, wherein the support layer is optionally formed of an inorganic material; and a metallic adhesion layer. The flexible substrate further comprises a polymer layer, wherein the support layer is between the polymer layer and the metallic adhesion layer.

By providing the support layer 110 between the polymer and the metallic adhesion layer, any material which is adhered to the metallic adhesion layer 108 is prevented from coming into contact with the polymer layer, thereby minimising or avoiding any contamination of the material by the polymer layer 1410. At the same time, the polymer layer 1410 can provide the necessary flexibility for provision of a macroscopic intermediate substrate 106. The flexible intermediate substrate 106 is mounted on a rigid substrate 1420, here a glass substrate, to facilitate the depositing and lifting processes described herein. In this example, the polymer is a layer of PDMS, but any other suitable polymer may be used in order to provide the desired flexibility to the intermediate substrate 106.

The large area transfer of 2D materials (or transfer of large area 2DMs) is now discussed in more detail with reference to FIG. 14. In this example, the 2DMs are CVD grown 2D materials. In this specific example, FIG. 14A shows the arrangement of a PDMS polymer 1410 supported support layer 110 (here implemented as a SiNₓ membrane) and layer thicknesses for the layers deposited on the support layer 110. In this example, as per the inset image, the support layer is formed as an 18 mm membrane, support by a glass slide 1420.

In FIG. 14B, a monolayer of WS₂ on a thick WS₂ heterostructure is fabricated using progressive stamping with the intermediate support substrate 106 of FIG. 14A. A cross pattern has been scratched into both layers to enable visualisation—the inset shows the arrangement of the two layers to highlight the covered areas, with the lower thick WS₂ 1450 covering the whole image and the (overlapping) upper monolayer WS₂ 1452 in the upper right part. In FIG. 14C, topography of the area in FIG. 14B indicated by the rectangle 1454 is shown. A height profile at the indicated position is shown in the inset image of FIG. 14C, measuring a step of approximately 0.7 nm. In FIG. 14D, an intensity map of the main WS₂ photoluminescence peak around 1.97 eV is shown. In FIG. 14E, a thin WS₂ layer is encapsulated in thick graphite, fabricated using the large area stamping method with the intermediate support substrate 106 of FIG. 14A. The bottom graphite layer covers the whole image frame, and the visible crystal is the upper graphite layer. In FIG. 14F, a map of the intensity of the WS₂ 2LA/E_{2g} Raman peak is shown. The peak is normalised by the Si peak. A representative Raman spectra (from the location indicated by the cross) is also shown. In FIG. 14G, a monolayer WS₂ CVD grown layer is shown after being transferred onto a mechanically exfoliated graphite crystal. A square pattern has been scratched into the WS₂ monolayer to enable visualisation.

The high-quality transfer of 2DMs using a flexible intermediate substrate is thus demonstrated at both the microscopic and macroscopic scale. The described transfer technique is simple and quick, reducing the cost and assembly time when e.g. forming or manufacturing VdW heterostructures.

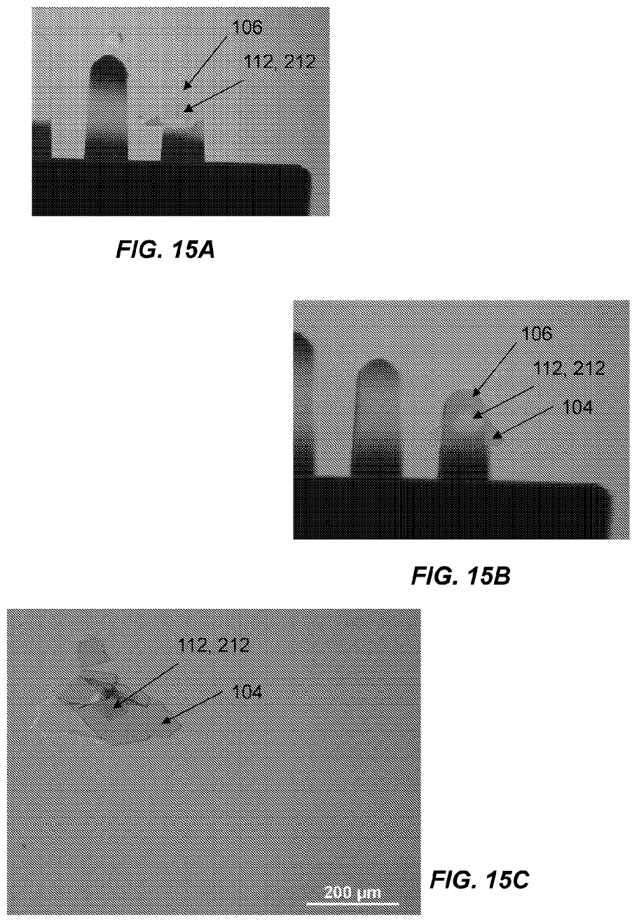

In the above-provided data, the metallic adhesion layer is formed of gold. In contrast, the following example uses a metallic adhesion layer formed of palladium, Pd (described with reference to FIG. 15). The intermediate substrate 106 is formed from an inorganic cantilever support layer 110 coated with a tri-metal stack consisting of: an optional interfacial layer 440 of 1 nm tantalum, Ta; an optional intermediary layer of 5 nm of platinum, Pt; and a metallic adhesion layer 108 of 0.1 nm to 1 nm of palladium, Pd. In this particular example, the Pd adhesion layer is 1 nm. The metallic adhesion layer was formed on the SiNₓ.

FIG. 15 shows optical micrographs of the transfer process. As shown in FIG. 15A, an exfoliated hBN crystal (material 112, 212) was picked up with the intermediate substrate 106. In FIG. 15B, the material is deposited (dropped off) onto a laterally large hBN crystal (the second substrate 104). After the material delaminates from the intermediate substrate 106, the flexible intermediate substrate 106 can be physically removed/moved away from the second substrate 104, leaving the material 112, 212 adhered to the second substrate 104 as shown in FIG. 15C.

It is experimentally demonstrated that the non-destructive delamination techniques described herein can be achieved with a metallic adhesion layer of Au and Pd, and for 2DMs of graphene, hBN and TMDC materials such as MoS₂. Following on from this experimental data, the skilled person would understand that other metals could be used for the metallic adhesion layer, as is already described herein. In particular, without wishing to be bound by theory, it is expected that any other metal with a binding energy (between the metal and the desired 2DM) close to or between the binding energies for the arrangements described experimentally herein can be used for the metallic adhesion layer 108. Literature examples of binding energies between graphene and various metals (Co, Ni, Pd, Ag, Au, Cu, Pt, Al) are given in Table 1 of Vanin et al. (2010, Graphene on metals: A van der Waals density functional study, Physical Review B, 81), and literature examples of binding energies between MoS₂ and various metals are given in Table 1 of Farmanbar et al. (2016, First-principles study of van der Waals interactions and lattice mismatch at MoS₂/metal interfaces, Physical Review B, 93).

In practice, the Van der Waals binding energy between the intermediate substrate and the material to be transferred is influenced by a combination of both chemical element composition and the nanoscale surface morphology of each of the metallic adhesion layer and the material to be transferred. The nanoscale surface morphology of the metallic adhesion layer can be adjusted by means of varying the metal deposition method, film thickness, underlying layers and environmental temperature or humidity. As such, it is expected that any other metal could function as a metallic adhesion layer provided the nanoscale surface morphology is tailored appropriately to achieve optimum VdW adhesion with the material to be transferred. In this regard, it will be understood by the skilled person that the choice of metallic adhesion layer may be application specific (i.e. dependent on the 2DM to be transferred or the type of heterostructure to be formed).

The non-destructive transfer technique and corresponding device described herein opens a pathway for improved industrial scale fabrication of various VdW heterostructures for both commercial and experimental purposes.

### Funding Statements

The project leading to this application has received funding from the European Union's Horizon 2020 research and innovation programme under grant agreement No 649953.

The project leading to this application has received funding from the European Research Council (ERC) under the European Union's Horizon 2020 research and innovation programme (grant agreement No 715502).

1. A method for transferring a material from a flexible intermediate substrate to a second substrate, the flexible intermediate substrate comprising a support layer and a metallic adhesion layer, the method comprising:
depositing the material from the intermediate substrate on to the second substrate, the depositing comprising adhering the material to the second substrate by Van der Waals adhesion between the material and the second substrate and delaminating the material from the metallic adhesion layer of the intermediate substrate.

2. The method of claim 1, wherein the depositing is a dry process.

3. The method of claim 1, wherein the support layer of the intermediate substrate is formed of an inorganic material.

4. The method of claim 3, wherein the support layer of the intermediate substrate comprises an oxide or a nitride.

5. The method of claim 4, wherein the support layer of the intermediate substrate comprises silicon nitride or silicon dioxide.

6. The method of claim 1, wherein the metallic adhesion layer comprises at least one of: gold, copper, platinum, chromium, or palladium.

7. The method of claim 1, further comprising an interfacial layer between the support layer and the metallic adhesion layer, the interfacial layer comprising at least one of: tantalum, chromium, titanium, tungsten, niobium, aluminium, or nickel.

8. The method of claim 1, further comprising controlling the Van der Waals adhesion at least in part by controlling a thickness and/or composition of the metallic adhesion layer.

9. The method of claim 1, further comprising controlling the Van der Waals adhesion at least in part by controlling a temperature of one or more of the substrates.

10. The method of claim 1, further comprising controlling the Van der Waals adhesion at least in part by controlling a speed of movement of the intermediate substrate.

11. The method of claim 1, further comprising lifting the material from a first substrate with the intermediate substrate, the lifting comprising adhering the material to the metallic adhesion layer by Van der Waals adhesion between the material and the metallic adhesion layer.

12. The method of claim 11, wherein:
lifting the material comprises bringing the metallic adhesion layer of the intermediate substrate proximate to the first substrate; and
depositing the material comprising bringing the metallic adhesion layer of the intermediate substrate proximate to the second substrate.

13. The method of claim 11, wherein the Van der Waals adhesion between the material and the metallic adhesion layer is greater than Van der Waals adhesion between the material and the first substrate.

14. The method of claim 11, wherein lifting the material comprises lifting a portion of the first substrate which is bonded to the material, the method further comprising:
removing the portion of the first substrate from the intermediate substrate before depositing the material on to the second substrate.

15. The method of claim 14, wherein removing the portion of the first substrate is a wet process.

16. The method of claim 11 11, further comprising:
patterning the support layer in accordance with a predetermined pattern and depositing the metallic adhesion layer on the patterned support layer; or
depositing the metallic adhesion layer on the support layer in accordance with a predetermined pattern;
wherein lifting the material comprising lifting the material in accordance with the predetermined pattern.

17. The method of claim 1, wherein the second substrate comprises an outer layer of a heterostructure having one or more layers, and wherein depositing the material on to the second substrate comprises depositing the material on the outer layer to form another layer of the heterostructure.

18. A method of forming a heterostructure by removing material from one or more substrates via a flexible intermediate substrate comprising a support layer and metallic adhesion layer, the method comprising:
lifting a first material from a first area of the one or more substrates with the intermediate substrate, the lifting comprising adhering the first material to the metallic adhesion layer by Van der Waals adhesion between the first material and the metallic adhesion layer; and
lifting a second material from a second area of the one or more substrates with the intermediate substrate, the lifting comprising adhering the second material to the first material by Van der Waals adhesion between the first material and the second material.

19. The method of claim 18, wherein the first area and the second area correspond to areas of a single substrate.

20. The method of claim 18, wherein the first area and the second area correspond to areas of two different substrates.

21. A flexible substrate for depositing material onto a bulk substrate, the flexible substrate comprising:
a support layer, wherein the support layer is formed of an inorganic material; and
a metallic adhesion layer.

22. The flexible substrate of claim 21, wherein the metallic adhesion layer comprises at least one of: gold, copper, platinum, chromium, or palladium.

23. The flexible substrate of claim 21, wherein:
wherein the support layer comprises a silicon nitride membrane, and wherein the silicon nitride membrane has a thickness of 200 nm to 1000 nm, optionally 500 nm; and/or
wherein the metallic adhesion layer comprises gold or palladium, and wherein the gold or palladium has a thickness between 0.01 nm and 10 nm, optionally between 0.05 nm and 5 nm, optionally between 0.1 nm and 1 nm.

24. The flexible substrate of claim 21, further comprising an interfacial layer between the support layer and the metallic adhesion layer, the interfacial layer comprising at least one of: tantalum, chromium, titanium, tungsten, niobium, aluminium, or nickel.

25. The flexible substrate of claim 21, further comprising a polymer layer, wherein the support layer is between the polymer layer and the metallic adhesion layer.
